(19) United States
(12) Patent Application Publication
(10) Pub. No.: US 2026/0211440 A1
(43) Pub. Date: Jul. 23, 2026

(54) SOFT SWITCHING LOW DROP-OUT REGULATOR

(71) Applicant: SAMSUNG ELECTRONICS CO., LTD., Suwon-si (KR)

(72) Inventors: Wanyeong Jung, Daejeon-si (KR); Jeongmyeong Kim, Daejeon-si (KR)

(73) Assignees: SAMSUNG ELECTRONICS CO., LTD., Suwon-si (KR); Korea Advanced Institute of Science and Technology, Daejeon (KR)

(21) Appl. No.: 19/456,705

(22) Filed: Jan. 22, 2026

(30) Foreign Application Priority Data
Jan. 23, 2025 (KR) 10-2025-0010141

(51) Int. Cl. G05F 1/59; G05F 1/575; H03K 17/06; H03K 17/13

(52) U.S. Cl. CPC G05F 1/59; G05F 1/575; H03K 17/063; H03K 17/133; H03K 2217/0036

(57) ABSTRACT

A soft switching low dropout (LDO) regulator includes a soft quantizer configured to output a plurality of voltage signals, an inverter-based buffer configured to receive the plurality of voltage signals and output a plurality of amplified or buffered voltage signals, and a power transistor array including a plurality of power transistors. An operation region of each of the plurality of power transistors is determined according to a corresponding amplified or buffered voltage signal.

### CROSS-REFERENCE TO RELATED APPLICATION

This application is based on and claims priority under 35 U.S.C. §119 to Korean Patent Application No. 10-2025-0010141, filed on January 23, 2025, in the Korean Intellectual Property Office, the disclosure of which is incorporated herein in its entirety by reference.

### BACKGROUND

The disclosure relates to a low drop-out (LDO) regulator, and more particularly, to a soft switching LDO regulator.

A system-on-chip (SoC) is an electronic system that integrates a processor, a memory, interfaces, peripheral devices, power management, and the like, into a single chip. The SoC is used in various products such as smartphones, Internet of Things (IoT) devices, automobiles, drones, smart home devices, and wearables.

Multiple voltage domains are required to supply power for various functional circuit blocks of the SoC. For stable voltage supply, an LDO regulator is utilized, and the LDO regulator may be embedded in various devices.

Analog or digital LDO regulators are commonly used as LDO regulators. Analog LDO regulators have no output ripple and provide an excellent power supply rejection (PSR), but there is a problem of a low current density and a high dropout voltage.

Digital LDO regulators provide a high current density and a high power efficiency, but there is a limit of generating an output voltage ripple and having a low PSR.

Accordingly, hybrid LDO regulators have been proposed to compensate for the shortcomings of analog LDO regulators and digital LDO regulators, but there is a problem that a complex circuit is needed to control two different parts in parallel.

In addition, hybrid LDO regulators have a low current density according to the main control structure responsible for most of the output current, and there is a limit of handling load current changes beyond certain boundaries.

### SUMMARY

The disclosure provides a soft switching low drop-out (LDO) regulator which provides a high power efficiency, a fast transient response, an output voltage without ripple, and a high current density, and is capable of being implemented in a small area.

According to an aspect of the disclosure, there is provided a soft switching LDO regulator which may include a soft quantizer configured to output a plurality of voltage signals, an inverter-based buffer configured to receive the plurality of voltage signals and output a plurality of amplified or buffered voltage signals, and a power transistor array including a plurality of power transistors, wherein an operation region of each power transistor is determined according to a corresponding amplification voltage signal.

The soft switching LDO regulator may further include an error amplifier configured to generate an error amplification signal by comparing an output voltage of the power transistor array changed according to a load current condition with a reference voltage.

The soft quantizer may output the plurality of voltage signals based on the error amplification signal output from the error amplifier.

The soft quantizer may have a plurality of transfer gates arranged in push-pull structure.

The soft quantizer may output the plurality of voltage signals, each of the plurality of voltage signals corresponding to each of a plurality of node voltages between two adjacent transfer gates among the plurality of transfer gates.

Each of the plurality of transfer gates may be a complementary metal oxide semiconductor (CMOS) transfer gate and may have a variable resistance value depending on a source-drain voltage.

The inverter-based buffer may include a first inverter circuit including first inverters that receive the plurality of voltage signals, a second inverter circuit including second inverters that receive the plurality of output signals from the first inverters and output the plurality of amplified voltage signals, and transfer gates connected to rear ends of the first inverters and rear ends of the second inverters.

Each of the first inverters and the second inverters may be a CMOS inverter.

The inverter-based buffer may be configured such that the plurality of voltage signals correspond to the first inverters on a one-to-one basis, the first inverters correspond to the second inverters on a one-to-one basis, and the plurality of voltage signals may be transmitted through a plurality of corresponding paths.

A bias current may flow between the first inverters or between the second inverters through the transfer gates in the inverter-based buffer.

The inverter-based buffer may output the plurality of amplified or buffered voltage signals within a rail-to-rail voltage range by the first inverter circuit and the second inverter circuit.

The inverter-based buffer may perform a biasing operation by using transistors operating in a triode region among the first inverters and the second inverters.

A gate-source voltage of transistors operating in the triode region may correspond to an input voltage in the inverter-based buffer.

Each of the first inverters and the second inverters may include a transistor configured with a minimum channel length.

Each of the plurality of power transistors may receive an amplified voltage signal at the gate terminal and operate in any one of a cut-off region, a subthreshold voltage region, a saturation region, and a triode region.

Some of the plurality of power transistors may operate in a complete turn-on state or a complete turn-off state depending on a load current, and the remaining power transistors may operate analogically to control a supply current supplied to a load, and control the supply current to match the load current.

Each of the plurality of power transistors may be a p-channel metal-oxide-semiconductor (PMOS) transistor.

### BRIEF DESCRIPTION OF DRAWINGS

Embodiments will be more clearly understood from the following detailed description taken in conjunction with the accompanying drawings in which:

FIGS. 1A and 1B are diagrams illustrating general low drop-out (LDO) regulators, respectively;

FIG. 2 is a diagram illustrating a configuration of a soft switching LDO regulator according to one or more embodiments;

FIGS. 3A to 3D are diagrams for explaining the structure of a soft quantizer according to one or more embodiments;

FIGS. 4A to 4D are diagrams for explaining the structure and operation of an inverter-based buffer according to one or more embodiments;

FIG. 5 is a diagram illustrating an operation of a power transistor array according to one or more embodiments; and

FIGS. 6A and 6B are diagrams illustrating an implementation example of a soft switching LDO regulator circuit according to one or more embodiments.

### DETAILED DESCRIPTION OF THE EMBODIMENTS

The embodiments described herein are non-limiting example embodiments, and thus, the disclosure is not limited thereto and may be realized in various other forms

In one or more embodiments described herein, a soft switching low drop-out (LDO) regulator with a single structure that integrates the advantages of analog/digital control used in an analog LDO regulator, a digital LDO regulator, and a hybrid LDO regulator is provided to solve the problems occurring in these LDO regulators.

Hereinafter, a soft switching LDO regulator according to one or more embodiments will be described with reference to the accompanying drawings. However, in the following description, when there is a risk of unnecessarily blurring the gist of the disclosure, a detailed description of a well-known function or configuration will be omitted.

In the disclosure, singular expressions include plural expressions unless explicitly specified as singular in context. In addition, plural expressions include singular expressions unless explicitly specified as plural in context. Throughout the disclosure, when a part includes a certain component, this means that other components may be further included rather than excluding other components unless otherwise stated.

In the accompanying drawings, the same reference numerals are assigned to the same or corresponding components. Furthermore, in the description of the following embodiments, redundant descriptions of the same or corresponding components may be omitted. However, even if a description of a component is omitted, it is not intended that such component is not included in any embodiment.

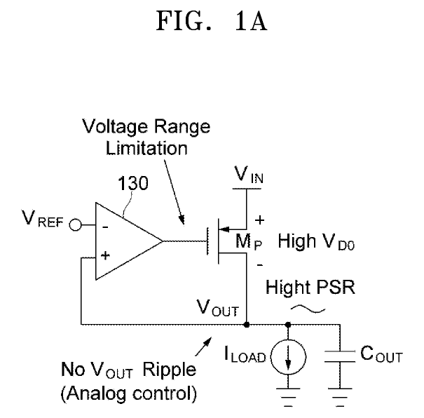

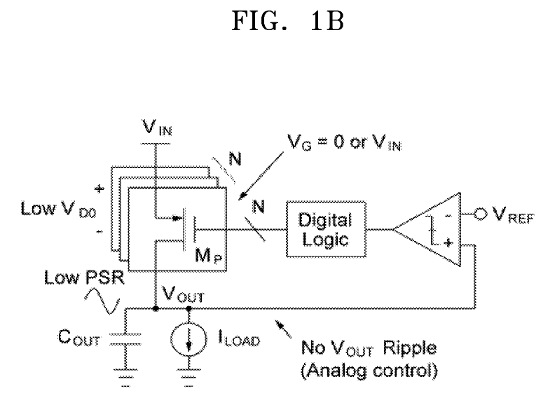

FIGS. 1A and 1B are diagrams illustrating general LDO regulators, respectively. FIG. 1A illustrates an analog LDO regulator structure, and FIG. 1B illustrates a digital LDO regulator structure.

Referring to FIG. 1A, the analog LDO regulator may detect a change in load current I_{LOAD} through an error amplifier 130 and adjust a gate voltage of a power transistor M_{P} to provide a required load current.

Since a range of an output voltage of the error amplifier 130 in the analog LDO regulator is affected by a structure of the error amplifier 130, there is a limit to a range of a gate voltage of the power transistor M_{P}.

In this case, since the power transistor M_{P} would not be driven by a source-gate voltage as an input voltage, a current density becomes low. In addition, since the power transistor M_{P} of the analog LDO regulator mainly operates in a saturation region, a large drop-out voltage of about 0.2 V is required, and thus a low power efficiency is exhibited. However, the analog LDO regulator may output a ripple-free output voltage V_{OUT} through an analog feedback loop and provide excellent power supply rejection ratio (PSR) performance.

Referring to FIG. 1B, the digital LDO regulator detects a change in a load current I_{LOAD} through a comparator and controls a power transistor M_{P} using a shift register to generate an output current.

Since a ground or input voltage V_{IN} may be input as a gate voltage of the digital LDO regulator, a source-gate voltage of the power transistor M_{P} may be driven by the input voltage V_{IN}, thus resulting in a high current density.

In addition, the digital LDO regulator may operate in a triode or cut-off region to provide a high power efficiency with a small drop-out voltage of about 50 mV. On the other hand, there is an output voltage ripple due to limit cycle oscillation (LCO) generated by digital control, and low PSR performance is exhibited.

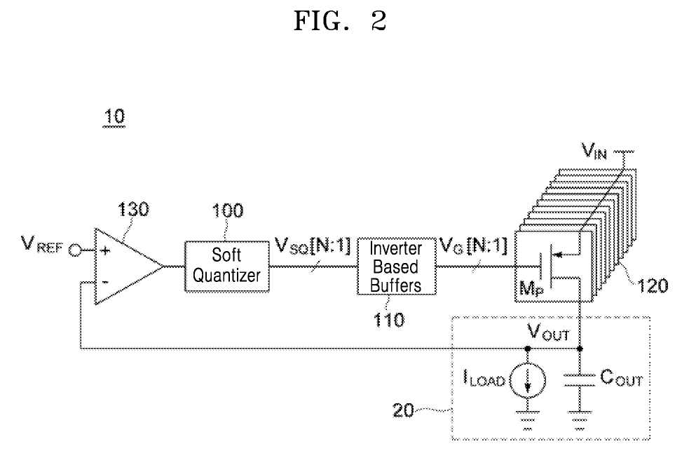

FIG. 2 is a diagram illustrating a configuration of a soft switching LDO regulator 10 according to one or more embodiments.

Referring to FIG. 2, the soft switching LDO regulator 10 may include a soft quantizer 100, inverter-based buffers 110, a power transistor array 120, and an error amplifier 130.

The soft switching LDO regulator 10 may output an output voltage V_{OUT} through the power transistor array 120 and supply a system load 20 with a load current I_{LOAD} corresponding to a current consumed by the system load 20.

The soft switching LDO regulator 10 may receive information regarding a change in the load current I_{LOAD} consumed by the system load 20. Accordingly, the output voltage V_{OUT} corresponding to the change in the load current I_{LOAD} may be adjusted to converge to a reference voltage V_{REF} through an analog feedback loop using the error amplifier 130.

The soft quantizer 100 may convert an error corresponding to an error amplification signal output from the error amplifier 130 into a soft digitized thermometer code. Accordingly, a voltage input to the power transistor array 120 is not limited to the ground 0 or an input voltage V_{IN}, and may have a voltage value of an intermediate level.

That is, transition from analog control to digital control may be smoothly processed, and signal distortion or discontinuity may be reduced.

The inverter-based buffers 110 may amplify a driving strength of a soft switching voltage signal transmitted from the soft quantizer 100 to output an amplified soft switching voltage signal.

The inverter-based buffers 110 may be configured in a structure in which buffers including inverters are connected in parallel with each other. Each voltage signal may move individually in each path corresponding to each buffer, and a signal amplified through the path may be input to a gate terminal of each corresponding power transistor to control operations of the power transistors.

The inverter-based buffers 110 may output a voltage signal in a rail-to-rail output voltage range. In addition, a stable bias condition is maintained through a parallel structure, and a fast transient response may be performed even in a transient state according to a change in the output voltage V_{OUT}.

The rail-to-rail output voltage range may be considered as a voltage range within the input voltage V_{IN} from the ground 0.

The power transistor array 120 may have a structure in which one large power transistor is divided into a plurality of small power transistors. The power transistor may be a PMOS transistor, and influence of capacitance may be reduced through a structure in which one large power transistor is divided into small power transistors.

A plurality of small power transistors may be connected in parallel with each other, and may operate by receiving a voltage signal amplified from the inverter-based buffers 110 as a gate voltage. Each of the power transistors may receive an output of each buffer present in a corresponding path as a gate voltage.

In addition, some power transistors may operate in a complete turn-on or turn-off state, and the remaining power transistors may continuously adjust output strengths of the transistors in an intermediate range.

Accordingly, even when there is a sudden change in the load current I_{LOAD} consumed by the system load 20, an output of the power transistor array 120 may be smoothly switched. In addition, the power transistor array 120 may be fully swing-controlled and an output strength may be maintained linearly.

In the present embodiment, transistors in the power transistor array 120 are assumed to be p-channel metal-oxide-semiconductor (PMOS) transistors, but are not limited thereto, and various power transistors such as n-channel metal-oxide-semiconductor (NMOS) transistors may be used. Herein, a PMOS transistor and an NMOS transistor are referred to as a PMOS and an NMOS, respectively.

The error amplifier 130 may receive an output voltage V_{OUT} corresponding to a load current through an analog feedback loop. In addition, an error amplification signal input to the soft quantizer 100 may be output by comparing the output voltage V_{OUT} with the reference voltage V_{REF}.

The soft quantizer 100 and the inverter-based buffers 110 may adjust an output signal based on an error amplification signal. According to the adjusted signal, the output strength may be controlled by adjusting the number of power transistors activated in the power transistor array 120, and soft switching may be performed.

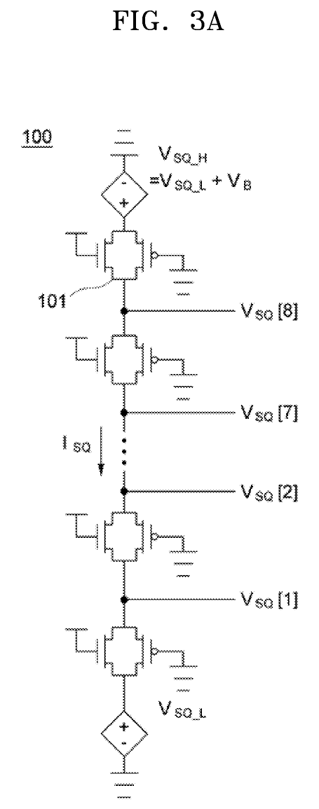

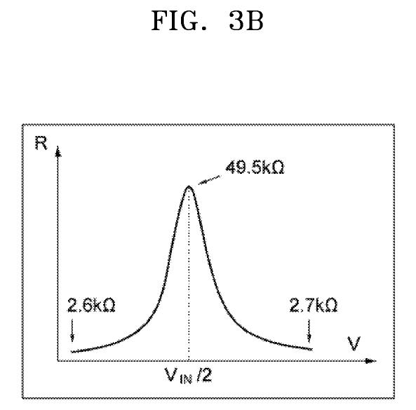

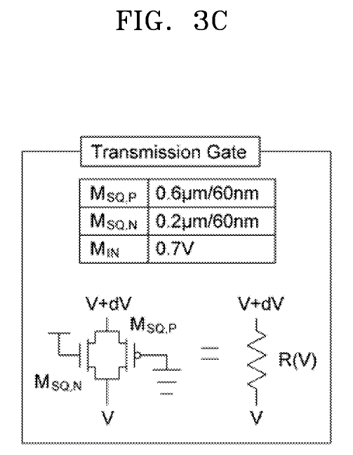

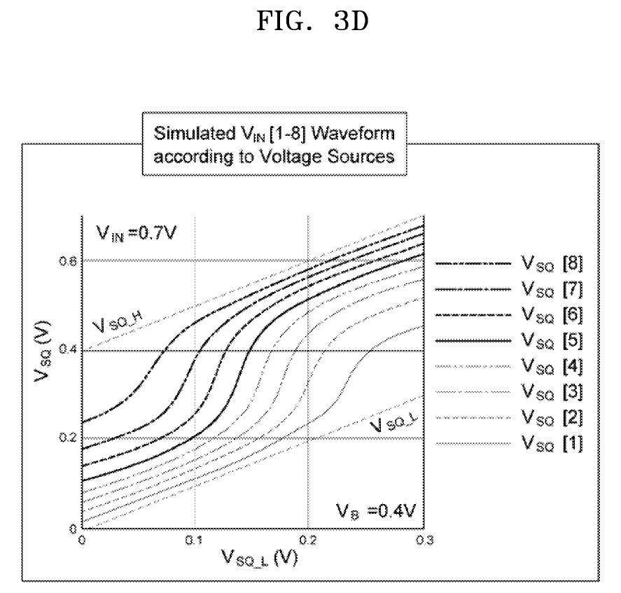

FIGS. 3A to 3D are diagrams for explaining a structure of a soft quantizer 100 according to one or more embodiments.

FIG. 3A shows the structure of the soft quantizer 100, and FIG. 3B is a graph showing resistance values according to a source-drain voltage of a transfer gate 101. In addition, FIG. 3C shows a structure of the transfer gate 101, and FIG. 3D shows a voltage graph according to nodes between the transfer gates 101.

Referring to FIG. 3A, the soft quantizer 100 may have a structure in which a plurality of transfer gates 101 are arranged in a push-pull structure. The number of transfer gates 101 may be set to any natural number.

The push-pull structure may mean a structure in which two active elements switch with each other and process a signal. In this case, the active elements may be transistors, and a PMOS transistor may be positioned at one end thereof and an NMOS transistor may be positioned at another end thereof.

Referring to FIGS. 3B and 3C, the transfer gate 101 may be a complementary metal-oxide-semiconductor (CMOS) gate including a PMOS and an NMOS, and may operate as a resistor. The transfer gate 101 may be a voltage dependent resistor having a resistance that is maximized when the source-drain voltage is around half of the input voltage, V_{IN}/2.

That is, the soft quantizer 100 may be a resistance divider between an upper voltage V_{SQ_H} and a lower voltage V_{SQ_L}, and may output a soft digitized output voltage V_{SQ}[N] based on a voltage distributed for each node positioned between the transfer gates 101. In this case, N is an arbitrary natural number. In this case, the soft digitized output voltages V_{SQ}[N] may correspond to a plurality of voltage signals on a one-to-one basis and may be output to the inverter-based buffers 110.

In this embodiment, only a case where eight output voltages V_{SQ}[N] are output from eight nodes is described as an example, but the disclosure is not limited thereto, and a voltage may be distributed in various stages and a signal may be transmitted to a path corresponding to the distributed voltage by adjusting the number of transfer gates.

The soft quantizer 100 is a variable voltage-dependent resistor in which a same current (I_{SQ}) passes through all the transfer gates 101 and the transfer gate 101 includes a resistance that is maximized around V_{IN}/2.

Accordingly, a voltage drop becomes the largest at a point where a resistance of a transfer gate 101 becomes the maximum. Accordingly, only a few output voltages are in the middle of the upper voltage V_{SQ_H} and the lower voltage V_{SQ_L}, and most of the output voltages are near the upper voltage V_{SQ_H} or the lower voltage V_{SQ_L}. That is, most of the output voltages V_{SQ}[N] may have voltage values adjacent to the upper voltage V_{SQ_H} and the lower voltage V_{SQ_L}.

Referring to FIG. 3D, when it is assumed that the input voltage V_{IN} is 0.7 V and a voltage difference V_{B} between the upper voltage V_{SQ_H} and the lower voltage V_{SQ_L} is 0.4 V, an output voltage V_{SQ}[N] of each node according to a change between the upper voltage V_{SQ_H} and the lower voltage V_{SQ_L} may be checked.

As described above, most of the output voltages V_{SQ}[N] have a value adjacent to the lower voltage V_{SQ_L} or the upper voltage V_{SQ_H}, and only a few output voltages V_{SQ}[N] have a value in the middle of the upper voltage V_{SQ_H} and the lower voltage V_{SQ_L}.

Accordingly, the output voltage V_{SQ}[N] near the upper voltage V_{SQ_H} may be amplified to be near the input voltage V_{IN} through the inverter-based buffers 110, and the output voltage V_{SQ}[N] near the lower voltage V_{SQ_L} may be amplified to be near the ground 0.

Thus, output voltages amplified through the inverter-based buffers 110 may be input to corresponding power transistors of the power transistor array 120, respectively, and the corresponding power transistors may be digitally controlled to operate completely turned on or off.

For example, if a power transistor operates in the triode region, the power transistor may be completely turned on, and if the power transistor operates in the cut-off region, the power transistor may be completely turned off.

In addition, an output voltage between the upper voltage V_{SQ_H} and the lower voltage V_{SQ_H} may be amplified through the inverter-based buffers 110 and then input to a corresponding power transistor of the power transistor array 120, and the power transistors may be analog-controlled in the intermediate range.

In this case, the intermediate range may mean that the power transistor operates in a subthreshold region or a saturation region.

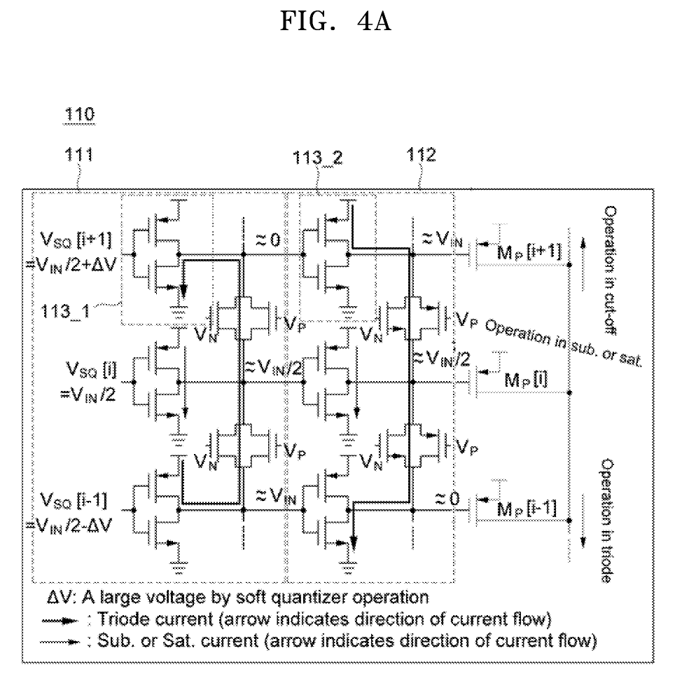

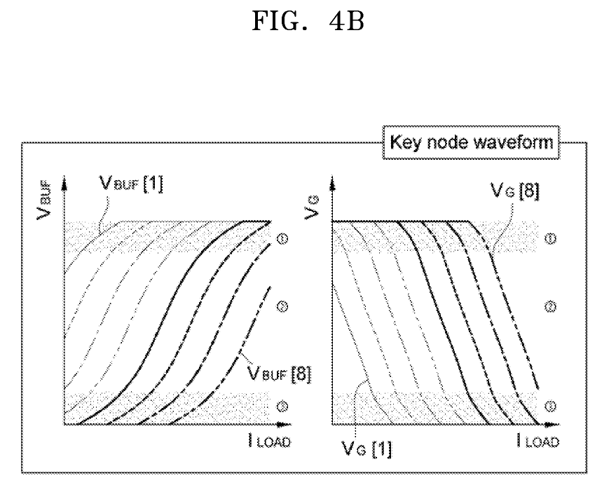

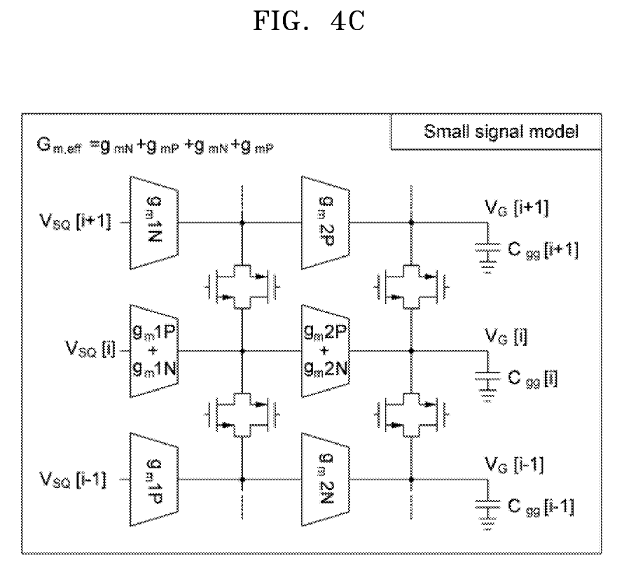

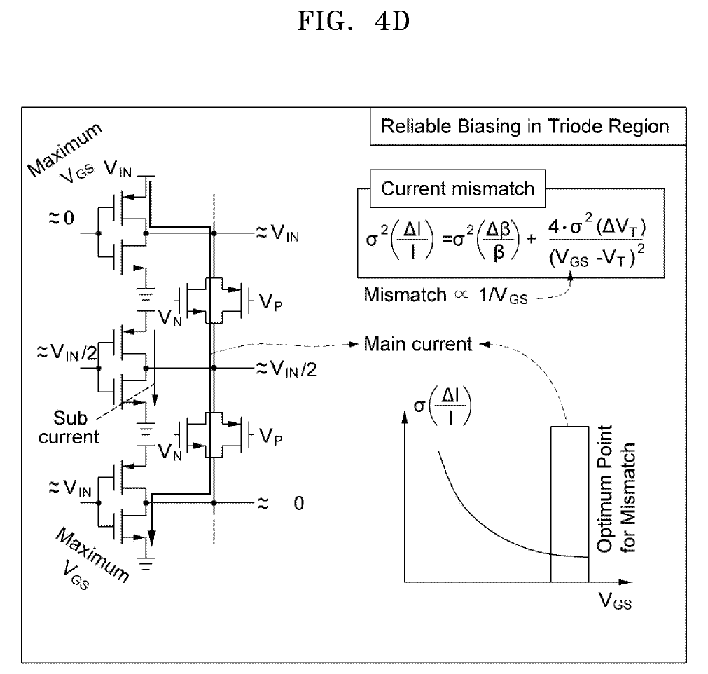

FIGS. 4A to 4D are diagrams for explaining a structure and an operation of an inverter-based buffers 110 according to one or more embodiments.

For example, FIG. 4A shows an example of an intermediate path operation of the inverter-based buffers 110, and FIG. 4B is a graph showing a node voltage according to an output of the inverter-based buffers 110. In addition, FIG. 4C shows a small signal model of the inverter-based buffers 110, and FIG. 4D shows an example of a biasing technique in the inverter-based buffers 110.

Referring to FIG. 4A, the inverter-based buffers 110 may include a first inverter circuit 111 in which a plurality of first inverters 113_1 are connected in parallel with each other and a second inverter circuit 112 in which a plurality of second inverters 113_2 are connected in parallel with each other.

Hereinafter, when common parts of the first inverter 113_1 and the second inverter 113_2 are described together, they will be described as inverters 113 for convenience.

The inverters 113 of each of the first inverter circuit 111 and the second inverter circuit 112 may be connected with each other in a one-to-one correspondence.

In addition, a transfer gate may be connected to an output end (a rear end) of each inverter 113, and may be between signal paths. In this case, the transfer gate 101 may be a CMOS gate.

Like flows of current indicated by solid line arrows in FIG. 4A, the inverter-based buffers 110 may adjust the number of active paths and a bias current value through the transfer gates in the circuit. In addition, a bias current may flow through an internal path.

The inverter 113 may be a CMOS inverter configured in a push-pull structure in which a PMOS is at one end and an NMOS is at another end. That is, the inverter 113 may be configured in a complementary form of two transistors and may adjust an output through a switching operation.

In addition, when an applied voltage is in a “high” or “low” state, the inverter 113 consumes little power because one transistor always operates in an off state, thereby improving power efficiency.

For example, when an input voltage of the inverter 113 is near V_{IN}/2, the inverter 113 may operate as an analog amplifier because both the PMOS and the NMOS operate in a saturation region. On the other hand, if the input voltage of the inverter 113 is lower or higher than a certain value, the PMOS or NMOS may operate as a digital buffer because the PMOS or NMOS operates in the cut-off or triode region.

To help understand the technical idea of the disclosure, the operation of the inverter-based buffers 110 will be described below for the cases in which the voltage input from the soft quantizer 100 to the inverter-based buffers 110 is high, V_{IN}/2, and low.

First, a soft switching voltage signal divided into several stages from the soft quantizer 100 is input to each first inverter 113_1 of the first inverter circuit 111. When the input voltage is high, the NMOS may be activated to operate in the triode region, and when the input voltage is low, the PMOS may be activated to operate in the triode region. When the input voltage is V_{IN}/2, PMOS and NMOS transistors may operate in a subthreshold or a saturation region.

Accordingly, a current corresponding to the triode region may flow through the transfer gates based on transistors operating in the triode region in the first inverter circuit 111. In addition, in the case of the first inverter 113_1 that receives V_{IN}/2 as the input voltage, a current corresponding to the saturation region may flow in the inside thereof.

The first inverter 113_1 receiving V_{IN}/2 as the input voltage may operate as an analog amplifier and may contribute to a loop gain of a circuit by using a bias current. The operation example described above may be similarly performed in the second inverter circuit 112.

An output of each first inverter 113_1 of the first inverter circuit 111 may be input to each second inverter 113_2 of the second inverter circuit 112. For example, an output V_{BUF}[N] of the first inverter circuit 111 is input to each second inverter 113_2 of the second inverter circuit 112, and the second inverter circuit 112 may output a gate voltage V_{G}[N] input to a power transistor.

For example, when a voltage input to a first inverter 113_1 of the first inverter circuit 111 is high, an output of a corresponding inverter may be a value adjacent to the ground 0, and an output of the corresponding inverter may be input to a corresponding second inverter 113_2 of the second inverter circuit 112 to output a value close to the input voltage VIN.

Even when a voltage input to the first inverter circuit 111 is V_{IN}/2 or low, the same operation as the above-described operation may be performed to finally output a value corresponding to V_{IN}/2 or the ground 0. Accordingly, the gate voltage may be output in a rail-to-rail voltage range through the inverter-based buffers 110.

Accordingly, each power transistor of the power transistor array 120 may receive a gate voltage in a rail-to-rail voltage range and may have a high current density.

Referring to FIG. 4B, voltages of each output node of the first inverter circuit 111 and the second inverter circuit 112 may be checked.

As shown in FIG. 4B, the voltage of an output node of each of most inverter-based buffers 110 has a high or low value. Therefore, little current is consumed, thereby increasing current efficiency.

In this case, the inverter 113 having an output within the intermediate range may operate as an analog amplifier and may contribute to the loop gain of the circuit. Furthermore, the bias current of the inverter-based buffers 110 may concentrate in an intermediate path inside the corresponding circuit.

Referring to FIG. 4C, each inverter 113 may be a CMOS inverter having a push-pull structure and may be connected to each other in a parallel structure. The transconductance of the inverter-based buffers 110 may be improved through the parallel structure and the push-pull structure, and a relatively high gain and bandwidth may be obtained compared to current consumption.

In addition, when the output voltage V_{OUT} by the power transistor array 120 changes according to a change in a load current I_{LOAD}, a feedback signal is transmitted to recover the output voltage V_{OUT} through an analog feedback loop.

Accordingly, a voltage signal input to the inverter-based buffers 110 may also be rapidly changed, and a transient state may be formed.

In a case of a transient state, in the inverter-based buffers 110 configured in a parallel structure, the inverters 113 in each parallel path are simultaneously activated to provide or consume large-scale current. For example, several parallel paths may be activated at the same time, and the inverters 113 may perform a switching operation like a digital switch. In addition, the transistor of the inverter 113 may slew while rapidly charging or discharging, and may have a high slew-rate.

Most transistors in each parallel path may be designed with a minimum channel length to minimize parasitic capacitance. The minimum channel length transistor may refer to a transistor having the shortest channel length implementable in a semiconductor manufacturing process.

Accordingly, it is possible to quickly respond to the transient state according to variation of the output voltage VOUT, and increase output stability.

Referring to FIG. 4D, when the transistor of the inverter 113 operates in a saturation region, there is a problem that a current mismatch between the transistors occurs. In addition, there is a limitation that it is difficult to utilize the inverter-based buffers 110 when the input voltage V_{IN} is low.

The inverter-based buffers 110 according to one or more embodiments may perform biasing using a parallel structure and a maximum gate-source voltage V_{GS}. For example, stable biasing using the current in the triode region may be provided through the transistor of the inverter 113 in which the gate-source voltage V_{GS} is adjacent to or identical to the input voltage V_{IN}. Accordingly, it is possible to overcome inconsistency between the transistors.

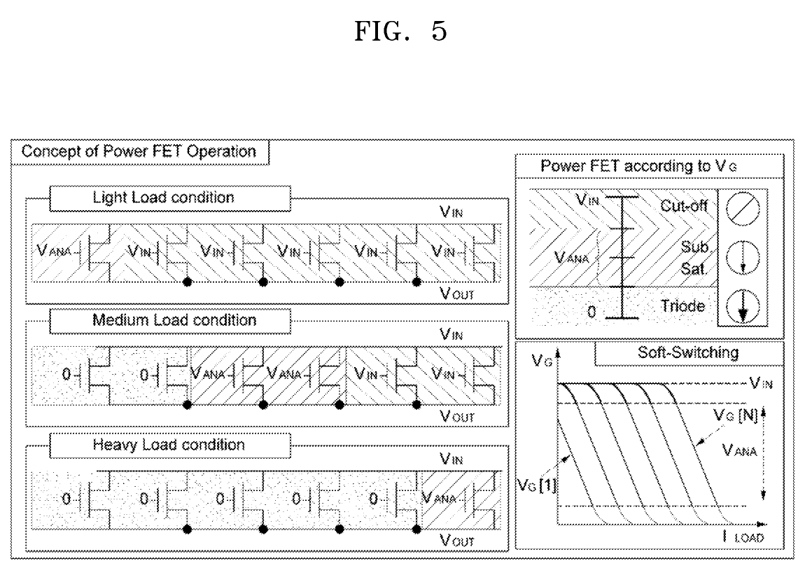

FIG. 5 is a diagram illustrating an operation of a power transistor array 120 according to one or more embodiments.

Referring to FIG. 5, the power transistor array 120 may be designed to have a structure in which one power transistor is divided into a plurality of small power transistors rather than using one large power transistor. Accordingly, capacitance of the power transistor may be reduced.

According to a change in a load current, the power transistors may operate in one of a cut-off region, a subthreshold voltage region, a saturation region, and a triode region.

For example, when the load current becomes very large, most of the power transistors may operate in the triode region. Accordingly, the current density may be improved, and a low drop-out voltage may be maintained.

In addition, a small number of power transistors may operate in subthreshold or saturated regions, and may output a ripple-free clean output voltage V_{OUT} through continuous analog control.

Each of the power transistors may receive a gate voltage from a buffer of the inverter-based buffers 110 connected in parallel. When the gate voltage is near the input voltage V_{IN} or the ground 0, the power transistor may operate in the cut-off or triode region, and may remain completely turned off or turned on. For example, when a voltage near the ground 0 is received, the power transistor may operate in the triode region, and when a voltage near the input voltage V_{IN} is received, the power transistor may operate as the cut-off region.

In addition, if the gate voltage is near V_{IN}/2, the power transistor may operate in the subthreshold region or saturation region and a strength of the power transistor may be adjusted in an intermediate range through analog control like an analog LDO regulator.

Accordingly, smooth switching may be performed while maintaining an overall strength of the power transistor linearly, and full-swing control is possible.

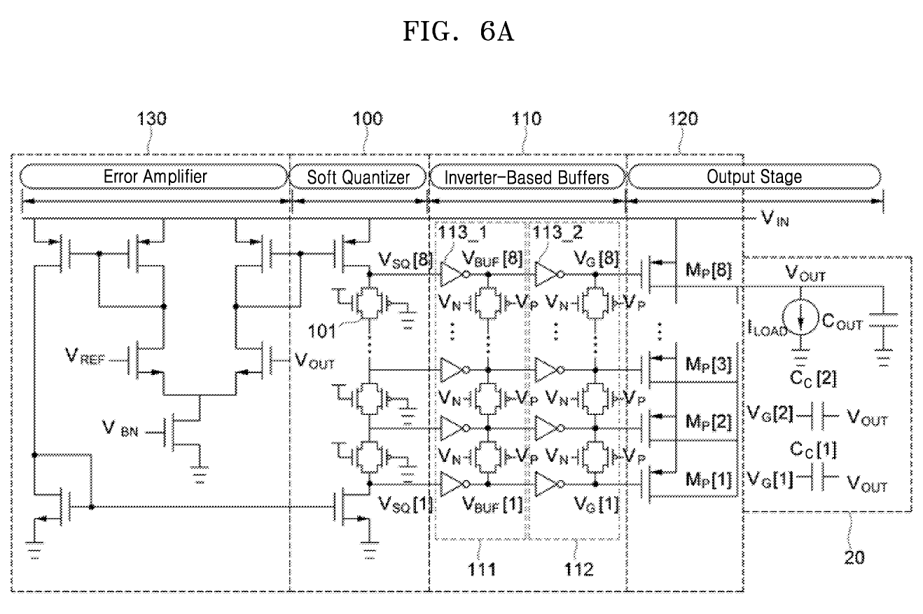

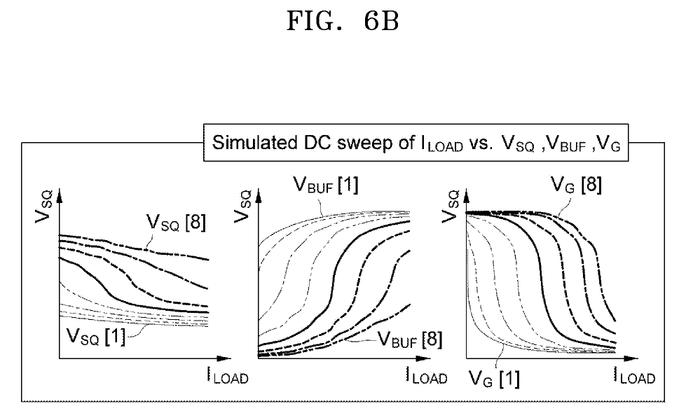

FIGS. 6A and 6B are diagrams illustrating an implementation example of a soft switching LDO regulator circuit according to one or more embodiments.

FIG. 6A shows a detailed circuit diagram of a soft switching LDO regulator 10 and operations of internal nodes, and FIG. 6B shows a DC sweep graph at an internal node according to a load current. The soft switching LDO regulator 10 shown in FIG. 6A may be the same as corresponding to the soft switching LDO regulator 10 shown in FIG. 2. Thus, the same reference numbers and characters may be used in the description below.

Referring to FIGS. 6A and 6B, the output node of the soft quantizer 100 is the V_{SQ} node, and the output node of the inverter-based buffers 110 is the V_{BUF} node and the V_{G} node. A signal output from the V_{G} node controls the power transistor M_{P}.

In the soft switching LDO regulator 10 according to an embodiment, since the V_{SQ} node, V_{BUF} node, and V_{G} node operate smoothly to supply a required supply current according to a load current, a stable biasing state may be maintained even under various load conditions through a soft switching operation.

Therefore, a pole frequency of the soft quantizer 100 and the inverter-based buffers 110 may be less affected by a change in the load current. In addition, the inverter-based buffers 110 may autonomously adjust a magnitude of current for each stage, and by using this, the V_{G} node, which is the output node of the second inverter circuit 112, is allowed to have a dominant pole.

The pole represents a point at which a gain in a frequency response decreases rapidly, and a pole occurring at each node inside the LDO regulator may affect the response speed and stability of the circuit.

On the other hand, due to the small size of the transistor, the poles of the V_{SQ} node and the V_{BUF} node may be at a high frequency and may respond quickly to changes in load current. Under light load conditions, the output may be unstable because the pole pf the output is at a low frequency, and this may be overcome by adding a compensation capacitor C_{C} to the V_{G} node.

Hereinafter, one or more embodiments showing performance of the soft switching LDO regulator 10 will be described.

The soft switching LDO regulator 10 may stably operate even with a small drop-out voltage of 50 mV in a wide voltage range of about 0.6 V to about 1 V, according to one or more embodiments.

In addition, the soft switching LDO regulator 10 may achieve -22 dB PSR with a 50 mV drop-out voltage through continuous control and may operate stably without output voltage ripple, according to one or more embodiments.

In addition, the soft switching LDO regulator 10 may perform a fast transient response using a “slew”-based charging and discharging mechanism using a parallel structure, according to one or more embodiments.

In addition, the power transistor is M_{P} driven by adjusting the gate voltage in a rail-to-rail voltage range, and a high current density of 31.3 A/mm² may be achieved through an efficient area structure.

Furthermore, the soft switching LDO regulator 10 may have a figure of merit (FoM) of 2.04 fs at an input voltage VIN of 0.6 V, which is the lowest voltage among operable voltages, according to one or more embodiments.

In the disclosure, terms such as “first” and “second” are used to distinguish a specific component from another component, and the components are not limited by these terms. For example, the “first” component may be an element of the same or similar form as the “second” component.

In the disclosure, unless otherwise defined, all terms used in the present specification, including technical or scientific terms, have the same meaning as those generally understood by those of ordinary skill in the art to which this concept belongs. In addition, commonly used terms, such as terms defined in dictionaries, should be interpreted as having meanings consistent with those in the context of related technologies.

While the disclosure has been particularly shown and described with reference to embodiments thereof, it will be understood that various changes in form and details may be made therein without departing from the spirit and scope of the following claims.

What is claimed is:

1. A soft switching low dropout (LDO) regulator comprising:
a soft quantizer configured to output a plurality of voltage signals;
an inverter-based buffer configured to receive the plurality of voltage signals and output a plurality of amplified or buffered voltage signals; and
a power transistor array comprising a plurality of power transistors,
wherein an operation region of each power transistor of the plurality of power transistors is determined according to a corresponding amplified or buffered voltage signal.

2. The soft switching LDO regulator of claim 1, further comprising an error amplifier configured to generate an error amplification signal by comparing an output voltage of the power transistor array changed according to a load current condition with a reference voltage.

3. The soft switching LDO regulator of claim 2, wherein the soft quantizer is configured to output the plurality of voltage signals based on the error amplification signal output from the error amplifier.

4. The soft switching LDO regulator of claim 1, wherein the soft quantizer comprises a plurality of transfer gates arranged in a push-pull structure.

5. The soft switching LDO regulator of claim 4, wherein the soft quantizer is configured to output the plurality of voltage signals, each of which corresponds to one of a plurality of node voltages between two adjacent transfer gates among the plurality of transfer gates.

6. The soft switching LDO regulator of claim 5, wherein each of the plurality of transfer gates comprises a complementary metal-oxide-semiconductor (CMOS) transfer gate and has a variable resistance value depending on a source-drain voltage.

7. The soft switching LDO regulator of claim 1, wherein the inverter-based buffer comprises:
a first inverter circuit comprising first inverters configured to receive the plurality of voltage signals;
a second inverter circuit comprising second inverters configured to receive a plurality of output signals from the first inverters and output the plurality of amplified voltage signals; and
transfer gates connected to rear ends of the first inverters and rear ends of the second inverters.

8. The soft switching LDO regulator of claim 7, wherein each of the first inverters and the second inverters comprises a complementary metal-oxide-semiconductor (CMOS) inverter.

9. The soft switching LDO regulator of claim 8, wherein the inverter-based buffer is configured such that the plurality of voltage signals correspond to the first inverters on a one-to-one basis, the first inverters correspond to the second inverters on a one-to-one basis, and the plurality of voltage signals are transmitted through a plurality of corresponding paths.

10. The soft switching LDO regulator of claim 9, wherein the inverter-based buffer is configured such that a bias current flows between the first inverters or between the second inverters through the transfer gates in the inverter-based buffer.

11. The soft switching LDO regulator of claim 10, wherein the inverter-based buffer is configured to output the plurality of amplified or buffered voltage signals within a rail-to-rail voltage range by the first inverter circuit and the second inverter circuit.

12. The soft switching LDO regulator of claim 11, wherein the inverter-based buffer is configured to perform a biasing operation by using transistors operating in a triode region among the first inverters and the second inverters.

13. The soft switching LDO regulator of claim 12, wherein the inverter-based buffer is configured such that a gate-source voltage of a transistor operating in the triode region corresponds to an input voltage.

14. The soft switching LDO regulator of claim 13, wherein each of the first inverters and the second inverters comprises a transistor configured with a minimum channel length.

15. The soft switching LDO regulator of claim 1, wherein each of the plurality of power transistors is configured to receive an amplified or buffered voltage signal at a gate terminal and operate in any one of a cut-off region, a subthreshold voltage region, a saturation region, and a triode region.

16. The soft switching LDO regulator of claim 15, wherein some of the plurality of power transistors are configured to operate in a complete turn-on state or a complete turn-off state depending on a load current, and remaining power transistors operate in an analog manner to control a supply current supplied to a load, and control the supply current to match the load current.

17. The soft switching LDO regulator of claim 16, wherein each of the plurality of power transistors includes a p-channel metal-oxide-semiconductor (PMOS) transistor.

18. A soft switching low dropout (LDO) regulator comprising:
a soft quantizer comprising a plurality of resistors configured to output a plurality of voltage signals;
an inverter-based buffer comprising a plurality of inverters connected in parallel configured to amplify or buffer the plurality of voltage signals; and
a power transistor array comprising a plurality of power transistors connected to the plurality of inverters, respectively, and configured to generate an output voltage based on the plurality of amplified or buffered voltage signals.

19. The soft switching LDO regulator of claim 18, wherein each of the plurality of resistors comprises a transfer gate comprising a p-channel transistor and an n-channel transistor.

20. The soft switching LDO regulator of claim 19, wherein the plurality of inverters comprise:
a plurality of first inverters connected in parallel;
a plurality of first transfer gates each of which is connected between two adjacent first inverters among the plurality of first inverters;
a plurality of second inverters connected in parallel; and
a plurality of second transfer gates each of which is connected between two adjacent second inverters among the plurality of second inverters,
wherein the plurality of first inverters and the plurality of second inverters are connected such that voltage signals output from the plurality of first inverters are respectively input to the plurality of second inverters.
